(19) United States
(12) Patent Application Publication
(10) Pub. No.: US 2026/0190753 A1
(43) Pub. Date: Jul. 2, 2026

(54) DISPLAY APPARATUS

(71) Applicant: LG Display Co., Ltd., Seoul (KR)

(72) Inventors: Juhoon JANG, Paju-si (KR); Myung-Soo PARK, Gimpo-si (KR); GyoHyun KOO, Seoul (KR)

(73) Assignee: LG Display Co., Ltd., Seoul (KR)

(21) Appl. No.: 19/421,968

(22) Filed: Dec. 16, 2025

(30) Foreign Application Priority Data
Dec. 31, 2024 (KR) 10-2024-0201957

(51) Int. Cl. H10K 59/80; G09G 3/3233

(52) U.S. Cl. CPC H10K 59/80515; G09G 3/3233; H10K 59/879; G09G 2300/0426; G09G 2300/0842; G09G 2300/0861; G09G 2320/068; G09G 2330/028; G09G 2380/10

(57) ABSTRACT

Provided is a display apparatus including a substrate in which a plurality of sub pixels is defined. Each subpixel includes a first light emitting diode having a first electrode, an emission layer, and a second electrode, and a plurality of second light emitting diodes also having a first electrode, an emission layer, and a second electrode. The first electrode of the first light emitting diode and the first electrodes of the plurality of second light emitting diodes may be integrally formed, while the second electrode of the first light emitting diode and the second electrodes of the plurality of second light emitting diodes are electrically separated. A lens is disposed on the first light emitting diode or the plurality of second light emitting diodes and is configured to control a path of light emitted from the diodes. Through this arrangement, the display apparatus allows selective control of viewing characteristics.

### CROSS-REFERENCE TO RELATED APPLICATIONS

This application claims the priority of Korean Patent Application No. 10-2024-0201957 filed on Dec. 31, 2024, in the Korean Intellectual Property Office, the disclosure of which is incorporated herein by reference.

### BACKGROUND

### Technical Field

The present disclosure relates to a display device, and more particularly, to a display device for controlling a viewing angle of an image.

### Description of the Related Art

The field of display devices for visually displaying electrical information signals is rapidly developing, and research continues to develop performances such as thinning, weight lightening, and low power consumption for various display devices.

Display devices are widely used in TVs and computer monitors, and recently have also been increasingly utilized as user interfaces of portable display devices and other electronic devices. In particular, as IT technology advances, display devices are also employed as vehicle instrument panels.

### BRIEF SUMMARY

The present disclosure relates to a display apparatus that provides controllable viewing angles through a modified sub pixel structure. Each sub pixel includes a first light emitting diode and multiple second light emitting diodes that share a common anode and emission layer while having electrically separated cathodes. By separating the cathodes, subsets of the light emitting diodes within a single sub pixel can be independently driven. This arrangement allows flexible control of image display while maintaining compatibility with conventional thin film transistor driving circuits.

The apparatus operates in two selectable modes. When power is supplied to all light emitting diodes in a sub pixel, the apparatus displays an image that is visible from a wide viewing angle, referred to as a share mode. When power is supplied only to a portion of the light emitting diodes, the image is visible from a narrow viewing angle, referred to as a privacy mode. The transition between these modes is achieved simply by controlling the divided cathode lines, which avoids significant changes to existing circuit designs.

The apparatus further includes lenses disposed above selected light emitting diodes to adjust the emission path and refine viewing angle characteristics. Examples include semi cylindrical or convex lenses placed over either all or some of the light emitting diodes in a sub pixel. Several structural variations are described, such as the use of shared or separate emission layers, shared or individual cathodes for the secondary light emitting diodes, and different lens arrangements. The disclosed structure is particularly suitable for displays in vehicles, portable devices, and other environments where both private viewing and shared viewing are required.

Various embodiments of the present disclosure provide a display apparatus capable of switching between a privacy mode for displaying an image at a narrow viewing angle and a share mode for displaying an image at a wide viewing angle.

Various embodiments of the present disclosure provide a display apparatus capable of controlling the privacy mode and the share mode while minimizing specification changes of a driving circuit.

Technical benefits of the present disclosure are not limited to the above-mentioned benefits, and other benefits, which are not mentioned above, can be clearly understood by those skilled in the art from the following descriptions.

According to an aspect of the present disclosure, there is provided a display apparatus. The display apparatus includes a substrate in which a plurality of sub pixels is defined. The display apparatus further includes a first light emitting diode disposed on the substrate in each of the plurality of sub pixels and including a first electrode, an emission layer, and a second electrode. The display apparatus further includes a plurality of second light emitting diodes disposed on the substrate in each of the plurality of sub pixels and including a first electrode, an emission layer, and a second electrode. And the display apparatus further includes a lens disposed on the first light emitting diode or the plurality of second light emitting diodes in the plurality of sub pixels and controlling a path of light emitted from the first light emitting diode or the plurality of second light emitting diodes. The second electrode of the first light emitting diode and the second electrode of the plurality of second light emitting diodes are electrically separated.

Other detailed matters of the exemplary embodiments are included in the detailed description and the drawings.

According to the present disclosure, by driving cathodes of a first light emitting diode and a second light emitting diode constituting one sub pixel in a divided manner, both the first light emitting diode and the second light emitting diode may be driven in a share mode to implement an image with a wide viewing angle, and only a part of the first light emitting diode and the second light emitting diode may be driven in a privacy mode to implement an image with a narrow viewing angle.

According to the present disclosure, switching between a share mode and a privacy mode may be achieved only by driving cathodes of a first light emitting diode and a second light emitting diode constituting one sub pixel in a divided manner, thereby providing control of the share mode and the privacy mode with minimal change in specifications of a pixel driving circuit.

The effects according to the present disclosure are not limited to the contents exemplified above, and more various effects are included in the present specification..

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is an example of a display apparatus according to an exemplary embodiment of the present disclosure;

FIG. 2 is a block diagram of a display apparatus according to an exemplary embodiment of the present disclosure;

FIG. 3 is a sub pixel circuit diagram of a display apparatus according to an exemplary embodiment of the present disclosure;

FIG. 4 is a plan view of a pixel of a display apparatus according to an exemplary embodiment of the present disclosure;

FIG. 5A is a plan view of a sub pixel of a display apparatus according to an exemplary embodiment of the present disclosure;

FIG. 5B is a perspective view of a lens of a display apparatus according to an exemplary embodiment of the present disclosure;

FIG. 6 is a cross-sectional view taken along line I-I′ of FIG. 5A;

FIG. 7 is a plan view of a pixel of a display apparatus according to another exemplary embodiment of the present disclosure;

FIG. 8 is a plan view of a sub pixel of a display apparatus according to another exemplary embodiment of the present disclosure;

FIG. 9 is a cross-sectional view taken along line II-II′ of FIG. 8;

FIG. 10 is a cross-sectional view taken along line III-III′ of FIG. 8;

FIG. 11 is a plan view of a pixel of a display apparatus according to still another exemplary embodiment of the present disclosure;

FIG. 12 is a plan view of a sub pixel of a display apparatus according to still another exemplary embodiment of the present disclosure;

FIG. 13 is a cross-sectional view taken along line IV-IV′ of FIG. 12; and

FIG. 14 is a cross-sectional view taken along line V-V′ of FIG. 12.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

As used herein, the term “connected” is intended to have the broadest possible meaning. Specifically, the phrase “A is connected to B” encompasses both a direct connection—where no intervening components or elements are present—and an indirect connection, where one or more intermediate components or elements exist between A and B. In other words, “A is connected to B” includes both direct physical or electrical coupling and indirect coupling through one or more intervening components. Unless explicitly stated otherwise, these terms do not require direct physical or electrical contact. The term “coupled” and “in contact” should be interpreted in the same manner.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

As used herein, the term “A or B” is intended to be construed as an inclusive disjunction. Unless expressly stated otherwise, “A or B” encompasses A alone, B alone, or A and B together. The recitation of alternatives using “or” is not intended to require mutual exclusivity unless such exclusivity is explicitly specified. Furthermore, where appropriate, “A or B” may be understood to include combinations, mixtures, or co-occurrence of the referenced elements.

Hereinafter, a display apparatus according to exemplary embodiments of the present disclosure will be described in detail with reference to accompanying drawings.

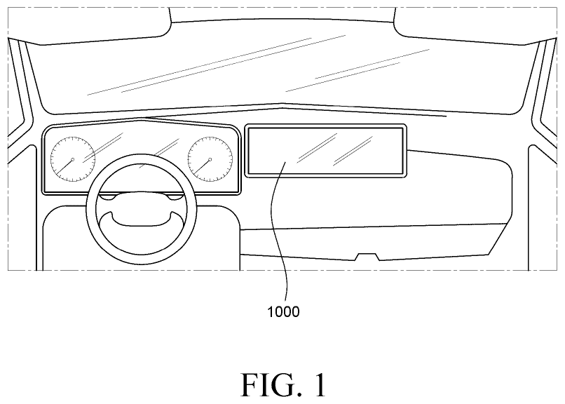

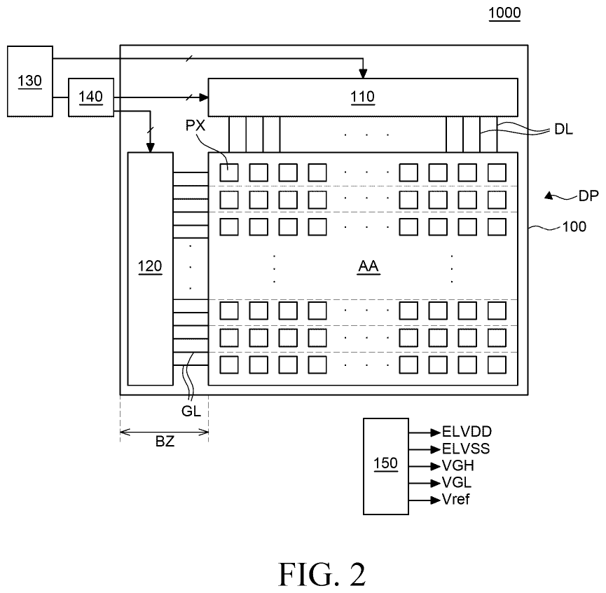

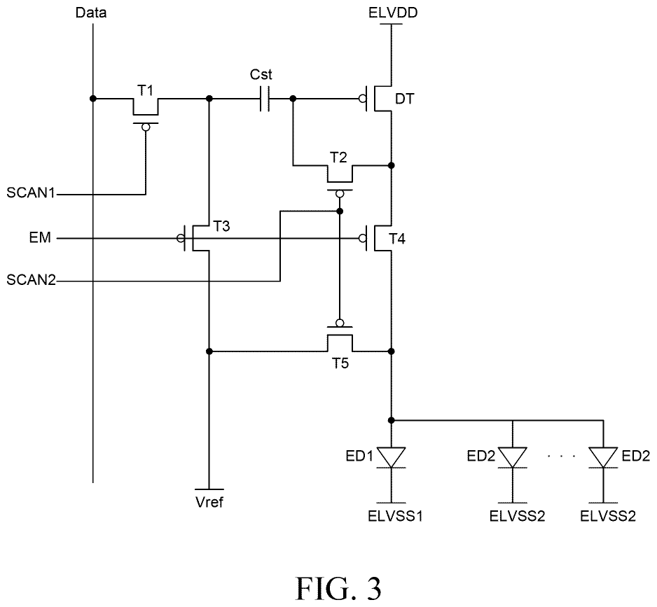

FIG. 1 is an example of a display apparatus according to an exemplary embodiment of the present disclosure. FIG. 2 is a block diagram of a display apparatus according to an exemplary embodiment of the present disclosure. FIG. 3 is a sub pixel circuit diagram of a display apparatus according to an exemplary embodiment of the present disclosure.

Referring to FIG. 1, a display apparatus 1000 according to an exemplary embodiment of the present disclosure may be a vehicle display apparatus, but is not limited thereto.

Hereinafter, as illustrated in FIG. 1, it will be described that the display apparatus 1000 according to an exemplary embodiment of the present disclosure is disposed on a dashboard and center fascia between a driver in a driver's seat and a passenger in a front passenger's seat of a vehicle, but is not limited thereto. In addition, in the following description, the left side of the display apparatus 1000 is defined as a first viewing direction facing the driver's seat, and the right side is defined as a second viewing direction facing the passenger's seat. However, the main viewing direction for a viewer watching an image displayed on the display apparatus 1000 is not limited thereto.

Referring to FIG. 2, the display apparatus 1000 may include a display panel DP, a data driving circuit 110, a gate driving circuit 120, and image processor 130, a timing controller 140, and a power supply unit 150.

The display panel DP may display an image to be provided to a user through a plurality of pixels PX disposed in an active area AA on a substrate 100.

The image processor 130 may output a data signal DATA and a data enable signal DE supplied from the outside. The image processor 130 may output, in addition to the data enable signal DE, one or more of a vertical synchronizing signal, a horizontal synchronizing signal, and a clock signal.

The timing controller 140 may control the data driving circuit 110 and the gate driving circuit 120. For example, the timing controller 140 may rearrange digital video data input from the image processor 130 in accordance with a resolution of the display panel DP and supply the rearranged data to the data driving circuit 110.

The timing controller 140 may receive driving signals including a data enable signal DE, or a vertical synchronizing signal, a horizontal synchronizing signal, and a clock signal from the image processor 130. Based on the driving signals, the timing controller 140 may output a gate timing control signal GDC for controlling the operation timing of the gate driving circuit 120 and a data timing control signal DDC for controlling the operation timing of the data driving circuit 110.

The data driving circuit 110 may convert digital video data RGB input from the timing controller 140 into an analog data voltage based on the data control signals, and supply the converted analog data voltage to a plurality of data lines DL.

The gate driving circuit 120 may generate a scan signal and an emission signal (or emission control signal) based on gate control signals. The gate driving circuit 120 may include a scan driver and an emission signal driver. The scan driver may generate the scan signal in a row sequential manner to drive at least one gate line GL connected to each pixel row, and supply the scan signal to the gate lines GL. The emission signal driver may generate the emission signal in a row sequential manner to drive at least one emission signal line connected to each pixel row, and supply the emission signal to the emission signal lines.

For example, the gate driving circuit 120 may be disposed on the display panel DP in a gate-driver in panel (GIP) method. For example, the gate driving circuit 120 may be divided into a plurality and disposed on at least two sides of the display panel DP, respectively.

The gate driving circuit 120 and the data driving circuit 110 may each be implemented by one or more integrated circuits and, in view of electrical connection with the display panel DP, may be implemented in types such as chip on glass (COG), chip on film (COF), or tape carrier package (TCP).

The gate driving circuit 120, the data driving circuit 110, and the timing controller 140 may provide signals for driving each pixel PX through signal lines. For example, the signal lines may include data lines DL and gate lines GL.

The power supply unit 150 may supply power to the data driving circuit 110 and the gate driving circuit 120. Through a power supply line connecting the power supply unit 150 and the display panel DP, a signal for driving a pixel PX may be provided. For example, the data driving circuit 110 may apply a data signal to each pixel PX through the data lines DL, and the gate driving circuit 120 may apply a gate signal to each pixel PX through the gate lines GL.

The power supply unit 150 may supply a high-potential power voltage ELVDD and a low-potential power voltage ELVSS to the pixel PX through a high-potential power line and a low-potential power line, respectively.

In addition, the power supply unit 150 may output a gate high voltage VGH, a gate low voltage VGL, and a reference voltage Vref. The gate high voltage VGH and the gate low voltage VGL are supplied to the gate driver 120, and constant voltages such as the high-potential power voltage ELVDD, the low-potential power voltage ELVSS, and the reference voltage Vref are supplied to sub pixels through power lines connected to pixel PX. In addition, the power supply unit 150 may supply a voltage such as a gamma reference voltage and the like to the data driver 110.

According to an exemplary embodiment of the present disclosure, the power supply unit 150 may independently supply the low-potential power voltage ELVSS through two or more low-potential power lines for one sub pixel. The display apparatus 1000 according to an exemplary embodiment of the present disclosure may receive from the timing controller 140, a control signal for making the power supply unit 150 independently output two or more low-potential power voltages ELVSS for one sub pixel, but is not limited thereto.

Referring to FIG. 2, a plurality of pixels PX may be disposed in the active area AA on the substrate 100 of the display panel DP. On the substrate 100, a plurality of data lines DL and a plurality of gate lines GL may intersect, and sub pixels configuring a pixel PX may be disposed at each intersection area. One pixel PX may include a plurality of sub pixels emitting different colors. For example, one pixel PX may be configured of a first sub pixel emitting red light, a second sub pixel emitting green light, and a third sub pixel emitting blue light, but is not limited thereto. For example, one pixel PX may further include a sub pixel for implementing a specific color (e.g., white) in addition to red, green, and blue. In a pixel PX, an area implementing blue may be referred to as a blue sub pixel area, an area implementing red may be referred to as a red sub pixel area, and an area implementing green may be referred to as a green sub pixel area. In an exemplary embodiment of the present disclosure, it is described that the display apparatus 1000 is an organic light emitting display apparatus. For example, a sub pixel of the display apparatus 1000 may include a light emitting diode including an anode electrode, an organic emission layer on the anode electrode, and a cathode electrode on the organic emission layer. The light emitting diode may further include a hole transport layer, a hole injection layer, an electron injection layer, and an electron transport layer, in addition to the organic emission layer.

The substrate 100 of the display panel DP may further include a non-active area around the active area AA, and the non-active area may be disposed along a periphery of the active area AA. Various components for driving a pixel driving circuit disposed together in an area where the pixel PX is disposed may be disposed in the non-active area. For example, at least a portion of the gate driving circuit 120 may be disposed in the non-active area. The non-active area may be referred to as a bezel area.

Referring to FIG. 2, a sub pixel of the display apparatus 1000 according to an exemplary embodiment of the present disclosure may include first light emitting diode ED1 and at least two second light emitting diodes ED2, and may include a pixel driving circuit for controlling an amount of current flowing through the first light emitting diode ED1 and each of the at least two second light emitting diodes ED2. The pixel driving circuit may include a plurality of thin film transistors (TFTs).

As illustrated in FIG. 2, the pixel driving circuit may include a driving transistor DT, a plurality of switching transistors T1 to T5, and a storage capacitor Cst. In addition, the pixel driving circuit is connected to signal lines including a data line to which a data voltage Data is applied, gate lines to which scan signals SCAN1 and SCAN2 and an emission signal EM are respectively applied, a high-potential power line to which a high-potential power voltage ELVDD is applied, a low-potential power line to which a low-potential power voltage ELVSS is applied, and a reference signal line to which a reference voltage Vref is applied. For example, among the gate lines GL, a wiring line to which scan signals are applied may be referred to as a scan line, and a wiring line to which an emission signal is applied may be referred to as an emission signal line.

In a pixel driving circuit of the display apparatus 1000 according to an exemplary embodiment of the present disclosure, except for the low-potential power voltage ELVSS among the signal lines supplying voltages to a sub pixel, the signal lines may be commonly connected to a plurality of sub pixels. The low-potential power voltage ELVSS may be divided and connected for each of the first light emitting diode ED1 and the plurality of second light emitting diodes ED2 in each of the plurality of sub pixels.

The scan signal and the emission signal may swing between a gate-on voltage and a gate-off voltage. For example, a transistor may be turned on in response to the gate-on voltage and turned off in response to the gate-off voltage. In the case of an n-channel transistor, the gate-on voltage may be a gate high voltage VGH and the gate-off voltage may be a gate low voltage VGL. In the case of a p-channel transistor, the gate-on voltage may be the gate low voltage VGL and the gate-off voltage may be the gate high voltage VGH.

A basic voltage level of the high-potential power voltage ELVDD is set to be higher than a maximum voltage of the data voltage Data, and to be a voltage at which the driving transistore DT may operate in a saturation area. An initialization voltage Vini may be set to be lower than the high-potential power voltage ELVDD and higher than the low-potential power voltage ELVSS. The gate high voltage VGH may be set to be higher than the high-potential power voltage ELVDD, and the gate low voltage VGL may be set to be lower than the low-potential power voltage ELVSS. For example, constant voltages applied to the pixel circuit may be set to ELVDD=+8 V, VSSEL=0 V, VGH=12.5 V, and VGL=−5 V, but are not limited thereto.

Among the plurality of thin film transistors in the pixel driving circuit, at least one may be an oxide semiconductor thin film transistor including a semiconductor layer of an oxide semiconductor, and the others may be transistors including a semiconductor layer of a polycrystalline semiconductor. For example, a transistor including a semiconductor layer of a polycrystalline semiconductor may be a low temperature poly silicon (LTPS) thin film transistor.

Each light emitting diode may operate to emit light according to a driving current formed by the driving transistor. The switching transistor may perform a switching operation such that a data signal supplied through data line DL is stored as a data voltage in a capacitor in response to a scan signal supplied through gate line GL. The driving transistor may operate such that a constant driving current flows between the high-potential power line and the low-potential power line in response to the data voltage stored in the capacitor.

Depending on types and characteristics of thin film transistors, a first electrode of each thin film transistor described below may be referred to as a source electrode or a drain electrode, and a second electrode may be referred to as a drain electrode or a source electrode.

The driving transistor DT has its first electrode connected to a high-potential power line supplying the high-potential power voltage ELVDD, its gate electrode connected to a first electrode of the storage capacitor Cst and a first electrode of a second transistor T2, and its second electrode connected to a second electrode of the second transistor T2.

The first transistor T1 has its first electrode connected to a data line supplying a data voltage Data its gate electrode connected to a scan line applying a first scan signal SCAN1, and its second electrode connected to a second electrode of the storage capacitor Cst and a first electrode of a third transistor T3.

The second transistor T2 has its first electrode connected to a first electrode of the storage capacitor Cst and a gate electrode of the driving transistor DT, its gate electrode connected to a second scan line applying a second scan signal SCAN2 and to a gate electrode of a fifth transistor T5, and its second electrode connected to a second electrode of the driving transistor DT and a first electrode of a fourth transistor T4.

The third transistor T3 has its first electrode connected to a second electrode of the first transistor T1 and a second electrode of the storage capacitor Cst, its gate electrode connected to an emission signal line supplying an emission signal EM and to a gate electrode of the fourth transistor T4, and its second electrode connected to a reference signal line applying the reference voltage Vref and a first electrode of the fifth transistor T5.

The fourth transistor T4 has its first electrode connected to a second electrode of the driving transistor DT and a second electrode of the second transistor T2, its gate electrode connected to the emission signal line supplying the emission signal EM and a gate electrode of the third transistor T3, and its second electrode connected to a second electrode of the fifth transistor T5 and a plurality of light emitting diodes ED1 and ED2.

The fifth transistor T5 has its first electrode connected to a reference signal line applying the reference voltage Vref and a second electrode of the third transistor T3, its gate electrode connected to the second scan line applying the second scan signal SCAN2 and a gate electrode of the second transistor T2, and its second electrode connected to a second electrode of the fourth transistor T4 and a plurality of light emitting diodes ED1 and ED2.

As illustrated in FIG. 3, an anode electrode of the first light emitting diode ED1 is connected to a second electrode of the fourth transistor T4 and a second electrode of the fifth transistor T5, and a cathode electrode thereof is connected to a low-potential power line supplying a first low-potential power voltage ELVSS1. In addition, an anode electrode of each of the plurality of second light emitting diodes ED2 is connected to the second electrode of the fourth transistor T4 and the second electrode of the fifth transistor T5, and a cathode electrode of each of the plurality of second light emitting diodes ED2 is connected to a low-potential power line applying a second low-potential power voltage ELVSS2. At this time, magnitudes of the first low-potential power voltage ELVSS1 supplied to the cathode electrode of the first light emitting diode ED1 and the second low-potential power voltage ELVSS2 supplied to the cathode electrodes of the plurality of second light emitting diodes ED2 are the same, but timings of application are different.

Meanwhile, in FIG. 3, a sub pixel of the display apparatus 1000 according to an exemplary embodiment of the present disclosure is illustrated as including one first light emitting diode ED1 and two second light emitting diodes ED2, but the number of the plurality of second light emitting diodes ED2 is not limited thereto.

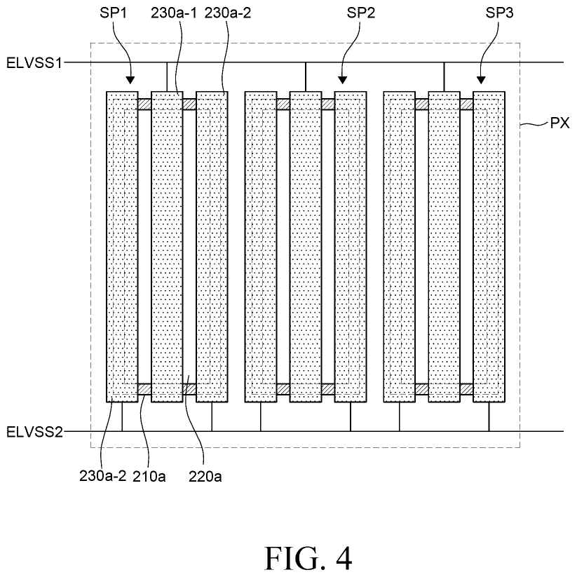

Hereinafter, referring to FIGS. 4 to 6, a pixel structure and a pixel driving method of the display apparatus 1000 according to an exemplary embodiment of the present disclosure will be described in detail.

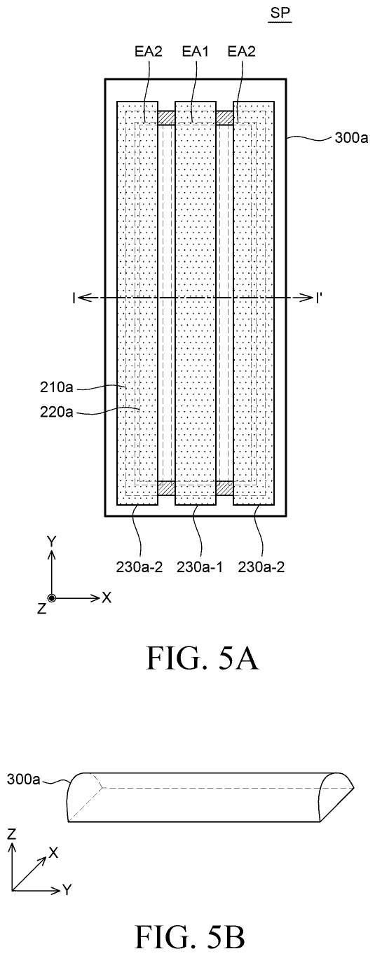

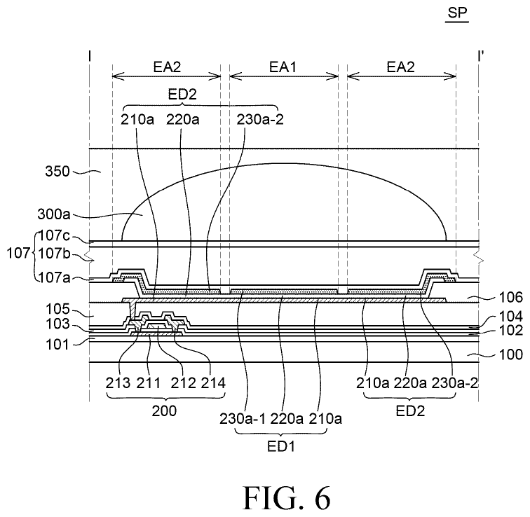

FIG. 4 is a plan view of a pixel of a display apparatus according to an exemplary embodiment of the present disclosure. FIG. 5A is a plan view of a sub pixel of a display apparatus according to an exemplary embodiment of the present disclosure. FIG. 5B is a perspective view of a lens of a display apparatus according to an exemplary embodiment of the present disclosure. FIG. 6 is a cross-sectional view taken along line I-I′ of FIG. 5A.

Referring to FIG. 4, one pixel PX of the display apparatus 1000 according to an exemplary embodiment of the present disclosure may include a first sub pixel SP1 emitting red light, a second sub pixel SP2 emitting green light, and a third sub pixel SP3 emitting blue light, but is not limited thereto.

In the first sub pixel SP1, the second sub pixel SP2, and the third sub pixel SP3, a wiring line supplying a first low-potential power voltage ELVSS1 is commonly connected, and separately, a wiring line supplying a second low-potential power voltage ELVSS2 is also commonly connected.

Each of the first sub pixel SP1, the second sub pixel SP2, and the third sub pixel SP3 may include one anode electrode 210a, one emission layer 220a disposed on the anode electrode 210a, and one first cathode electrode 230a-1 and two second cathode electrodes 230a-2 disposed on the one emission layer 220a. At this time, a first low-potential power line supplying the first low-potential power voltage ELVSS1 is connected to the first cathode electrode 230a-1. The two second cathode electrodes 230a-2 are respectively connected to second low-potential power lines supplying the second low-potential power voltage ELVSS2.

The one first cathode electrode 230a-1 and the two second cathode electrodes 230a-2 may be disposed spaced apart in three along a width direction of the emission layer 220a, but a direction in which they are spaced apart is not limited thereto. In addition, on one sub pixel, the first cathode electrode 230a-1 may be disposed in the center, and the second cathode electrodes 230a-2 may be disposed on both sides of the first cathode electrode 230a-1, but is not limited thereto.

Accordingly, as illustrated in FIG. 6, one sub pixel may include the first light emitting diode ED1 including the anode electrode 210a, the emission layer 220a, and the first cathode electrode 230a-1. In addition, one sub pixel may include one second light emitting diode ED2 including the anode electrode 210a, the emission layer 220a, and one second cathode electrode 230a-2. Further, one sub pixel may include another second light emitting diode ED2 including the anode electrode 210a, the emission layer 220a, and the other second cathode electrode 230a-2.

As such, one sub pixel may include one first light emitting diode ED1 and two second light emitting diodes ED2, and the anode electrode 210a and the emission layer 220a of the one first light emitting diode ED1 are integrally formed with the anode electrode 210a and the emission layer 220a of the two second light emitting diodes ED2, respectively. In addition, the cathode electrode 230a-1 of the one first light emitting diode ED1 and the cathode electrodes 230a-2 of the two second light emitting diodes ED2 are electrically separated.

Meanwhile, referring to FIGS. 5A to 6 together, the display apparatus 1000 according to an exemplary embodiment of the present disclosure may include lens 300a disposed to cover an emission area EA1 of the one first light emitting diode ED1 and emission areas EA2 of the two second light emitting diodes ED2 in each sub pixel SP. In FIG. 5A, one lens 300a covering the emission area EA1 of the first light emitting diode ED1 and the emission areas EA2 of the two second light emitting diodes ED2 is illustrated as being disposed in one sub pixel SP, but is not limited thereto. For example, the lens 300a may be disposed to cover only the emission area EA1 of the first light emitting diode ED1.

As illustrated in FIG. 5B, the lens 300a may be a semi-cylindrical lens extending along a first direction (e.g., a Y direction). However, a shape of the lens 300a of the display apparatus 1000 according to an exemplary embodiment of the present disclosure is not limited thereto, and conditions such as a height, pitch, curvature, and refractive index of the lens 300a may be changed depending on optical characteristics to be implemented through the display apparatus 1000. For example, the lens 300a may be a convex lens having a circular bottom surface and a hemispherical cross-section.

For example, in FIG. 6, the lens 300a may be cylindrical as illustrated in FIG. 5B, but FIG. 5 illustrates the lens 300a in a simplified manner to show a disposition relationship of the lens 300a.

As illustrated in FIG. 5A, a cathode electrode 230a-1 of the first light emitting diode ED1 and cathode electrodes 230a-2 of the two second light emitting diodes ED2 may each extend along a longitudinal direction in which the lens 300a extends.

Referring to FIGS. 5A and 6 together, the display apparatus 1000 may include the substrate 100 of the display panel DP, a buffer layer 101 disposed on the substrate 100, a transistor 200 disposed on the buffer layer 101, a gate insulating layer 102 disposed on the buffer layer 101, an interlayer insulating layer 103 disposed on the gate insulating layer 102, an inorganic insulating layer 104 disposed on the interlayer insulating layer 103, a planarization layer 105 disposed on the inorganic insulating layer 104, a first light emitting diode ED1 and a plurality of second light emitting diodes ED2 disposed on the planarization layer 105, and a bank 106 disposed on the planarization layer 105 to define emission areas of the first light emitting diode ED1 and the plurality of second light emitting diodes ED2. In addition, the display apparatus 1000 may include an encapsulation layer 107 disposed on the bank 106 and the light emitting diodes ED1 and ED2, the lens 300a disposed on the encapsulation layer 107 and overlapping with the first light emitting diode ED1 and the plurality of second light emitting diodes ED2, and a lens protective layer 350 covering the lens 300a.

The substrate 100 may be formed of a hard material such as glass, or may be formed of a plastic-based material such as polyimide, but is not limited thereto.

The buffer layer 101 may be formed over an entire surface of the substrate 100. The buffer layer 101 may improve adhesion between the substrate 100 and layers formed on the buffer layer 101. The buffer layer 101 may be formed of a single layer or multiple layers of SiNx or SiOx, but is not limited thereto. In addition, the buffer layer 101 may be omitted depending on a type and material of the substrate 100, or a structure and type of thin film transistor disposed above.

The thin film transistor 200 electrically connected to the first light emitting diode ED1 is disposed on the buffer layer 101. In FIG. 6, for convenience of explanation, only a driving thin film transistor among various thin film transistors that may be included in the display apparatus 1000 is illustrated, but a sub pixel SP may further include switching thin film transistors, capacitors, and the like.

The thin film transistor 200 is disposed on the buffer layer 101, and may include a semiconductor pattern 211 including a channel region in the center and source and drain regions as doped layers on both sides of the channel region, a gate electrode 212 disposed on the gate insulating layer 102 covering the semiconductor pattern 211 to overlap the semiconductor pattern 211, and a source electrode 213 and a drain electrode 214 disposed on the interlayer insulating layer 103 covering the gate electrode 212 and electrically connected to the semiconductor pattern 211, respectively. The source electrode 213 and the drain electrode 214 may be contacted with the source region and drain region of the semiconductor pattern 211 through contact holes formed in the gate insulating layer 102 and the interlayer insulating layer 103.

For example, the semiconductor pattern 211 may be formed of an oxide semiconductor such as indium gallium zinc oxide (IGZO), indium zinc oxide (IZO), indium gallium tin oxide (IGTO), or indium gallium oxide (IGO), but is not limited thereto. As another example, the semiconductor pattern 211 may be formed of a polycrystalline semiconductor of low temperature poly silicon (LTPS) having high mobility, but is not limited thereto.

The gate insulating layer 102 may be formed of a single layer or multiple layers of inorganic materials such as SiOx or SiNx, but is not limited thereto.

The interlayer insulating layer 103 may be formed of at least one of an organic material such as photo acrylic, and an inorganic material such as SiNx or SiOx, and may be formed of a single layer or multiple layers thereof, but is not limited thereto.

The gate electrode 212, the source electrode 213, and the drain electrode 214 may each be formed of a metal such as molybdenum (Mo), aluminum (Al), chromium (Cr), gold (Au), titanium (Ti), nickel (Ni), neodymium (Nd), or copper (Cu), and may be formed of a single layer or multiple layers made of any one of these metals or an alloy thereof, but is not limited thereto.

The inorganic insulating layer 104 is disposed on the thin film transistor 200 and the interlayer insulating layer 103. The inorganic insulating layer 104 may block unnecessary electrical connections between components of the thin film transistor 200 and may block contamination or damage from the outside. For example, the inorganic insulating layer 104 may be formed of a material such as silicon oxide (SiOx) or silicon nitride (SiNx).

The planarization layer 105 is disposed on the inorganic insulating layer 104.

The planarization layer 105 may be formed of an organic material such as photo acrylic, but is not limited thereto. For example, the planarization layer 105 may be configured of a plurality of layers including an inorganic layer and an organic layer.

The planarization layer 105 protects the thin film transistor 200 and alleviates steps generated due to the thin film transistor 200. In addition, the planarization layer suppresses parasitic capacitance that may be generated between the thin film transistor 200 and the gate lines, data lines, and light emitting diodes 300.

In each sub pixel SP, a first light emitting diode ED1 and a plurality of second light emitting diodes ED2 emitting light of the same color are disposed on the planarization layer 105.

The first light emitting diode ED1 includes a first electrode 210a electrically connected to the thin film transistor 200 through a contact hole formed in the planarization layer 105, the emission layer 220a disposed on the first electrode 210a, and a second electrode 230a-1 disposed on the emission layer 220a. At this time, the first electrode 210a may be an anode electrode, and the second electrode 230a-1 may be a cathode electrode.

In addition, the two second light emitting diodes ED2 each include the first electrode 210a electrically connected to the thin film transistor 200 through a contact hole formed in the planarization layer 105, the emission layer 220a disposed on the first electrode 210a, and the second electrode 230a-2 disposed on the emission layer 220a. At this time, the first electrode 210a may be an anode electrode, and the second electrode 230a-2 may be a cathode electrode.

That is, as illustrated in FIG. 6, the first light emitting diode ED1 and the two second light emitting diodes ED2 share one first electrode 210a and one emission layer 220a, but second electrodes of the first light emitting diode ED1 and the two second light emitting diodes ED2 are electrically separated.

Meanwhile, the first electrode 210a of each of the first light emitting diode ED1 and the two second light emitting diodes ED2 may be formed of at least one or more of silver (Ag), aluminum (Al), gold (Au), molybdenum (Mo), tungsten (W), chromium (Cr), ytterbium (Yb), or an alloy thereof, but is not limited thereto. In addition, the first electrode 210a may be formed of a transparent metal oxide layer such as indium tin oxide (ITO) or indium zinc oxide (IZO), and may further include an opaque conductive material in order to serve as a reflective electrode reflecting light. The second electrodes 230a-1 and 230a-2 of the first light emitting diode ED1 and the two second light emitting diodes ED2 may be formed of a semitransparent conductive material transmitting light. The second electrodes 230a-1 and 230a-2 may be formed of at least one or more of alloys such as LiF/Al, CsF/Al, Mg:Ag, Ca/Ag, Ca:Ag, LiF/Mg:Ag, LiF/Ca/Ag, or LiF/Ca:Ag, but are not limited thereto. The second electrodes 230a-1 and 230a-2 may be configured of a transparent metal oxide such as indium tin oxide (ITO) or indium zinc oxide (IZO), but are not limited thereto.

In addition, the encapsulation layer 107 is disposed to cover the first light emitting diode ED1 and the two second light emitting diodes ED2.

The encapsulation layer 107 serves to protect the first light emitting diode ED1 and the two second light emitting diodes ED2 from being exposed to impurities such as moisture or oxygen. For example, as illustrated in FIG. 6, the encapsulation layer 107 may be configured of a plurality of layers including a first encapsulation layer 107a, a second encapsulation layer 107b, and a third encapsulation layer 107c, but is not limited thereto. The first encapsulation layer 107a and the third encapsulation layer 107c may be formed of an inorganic material such as SiOx or SiNx, but are not limited thereto. The second encapsulation layer 107b may be formed of an organic insulating material such as acrylic resin, epoxy resin, polyimide, polyethylene, or silicon oxycarbide (SiOC), but is not limited thereto.

The lens 300a is disposed on the encapsulation layer 107, and the lens protective layer 350 covering the lens 300a is disposed on the encapsulation layer 107 and the lens 300a. An organic insulating layer as an optical gap layer for securing an optical distance between the light emitting diode and the lens may be disposed between the encapsulation layer 107 and the lens 300a.

The lens 300a controls a path of light emitted from the first light emitting diode ED1 and the two second light emitting diodes ED2. The lens 300a of the display apparatus 1000 according to an exemplary embodiment of the present disclosure may be a semi-cylindrical lens that is long in a vertical direction (i.e., a Y direction) and narrow in a horizontal direction (i.e., an X direction), and may have a hemispherical cross-section. Accordingly, the lens 300a may limit left and right viewing angles and broaden top and bottom viewing angles.

The lens protective layer 350 may be a planarization film covering the lens 300a. In order that light refracted in a particular direction on a surface of the lens 300a proceeds in an originally set direction, the lens protective layer 350 may be formed of a material having a refractive index lower than a refractive index of the lens 300a. For example, the lens protective layer 350 may be formed of oil having a low refractive index, but is not limited thereto. For example, the lens protective layer 350 may include an organic insulating material having a refractive index lower than that of the lens 300a.

Meanwhile, the display apparatus 1000 according to an exemplary embodiment of the present disclosure may selectively provide a share mode displaying an image in a wide viewing angle and a privacy mode displaying an image in a narrow viewing angle depending on a user's selection.

When the share mode is selected, power supply unit 150 supplies low-potential power voltage ELVSS to both the first light emitting diode ED1 and the two second light emitting diodes ED2. Accordingly, the first low-potential power voltage ELVSS1 is applied to the second electrode 230a-1 of the first light emitting diode ED1 so that the first light emitting diode ED1 emits light, and the second low-potential power voltage ELVSS2 is applied to the second electrodes 230a-2 of the two second light emitting diodes ED2 so that the two second light emitting diodes ED2 also emit light. Thus, in the share mode, both the first light emitting diode ED1 and the two second light emitting diodes ED2 emit light to display an image in a wide viewing angle.

On the other hand, when the privacy mode is selected, the power supply unit 150 supplies low-potential power voltage ELVSS only to the first light emitting diode ED1 among the first light emitting diode ED1 and the two second light emitting diodes ED2. Accordingly, the first low-potential power voltage ELVSS1 is applied to the second electrode 230a-1 of the first light emitting diode ED1 so that the first light emitting diode ED1 emits light, but the low-potential power voltage is not applied to the second electrodes 230a-2 of the two second light emitting diodes ED2, so that the two second light emitting diodes ED2 do not operate. Thus, in the privacy mode, only the first light emitting diode ED1 disposed between the two second light emitting diodes ED2 in a sub pixel SP emits light to display an image in a narrow viewing angle.

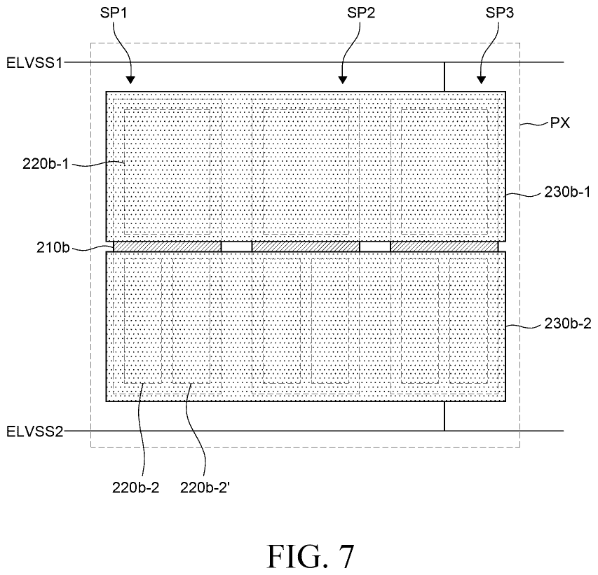

Next, referring to FIGS. 7 to 10, a pixel structure and a pixel driving method of a display apparatus according to another exemplary embodiment of the present disclosure will be described in detail. For convenience of explanation, in FIGS. 7 to 10, descriptions overlapping with those of FIGS. 4 to 6 will be omitted.

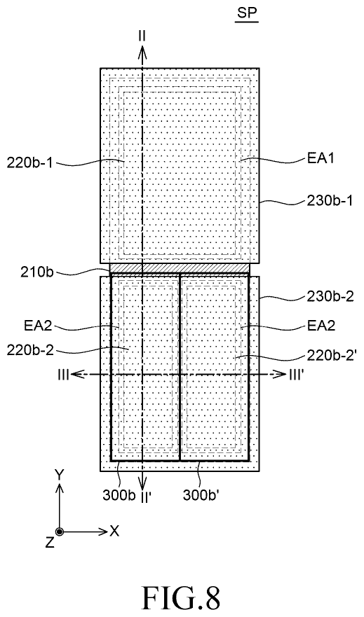

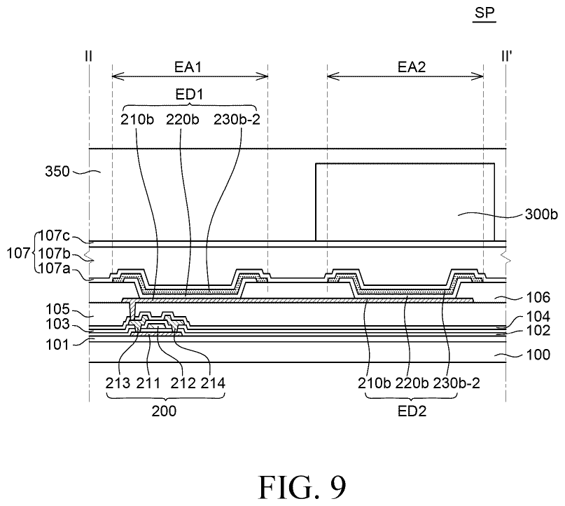

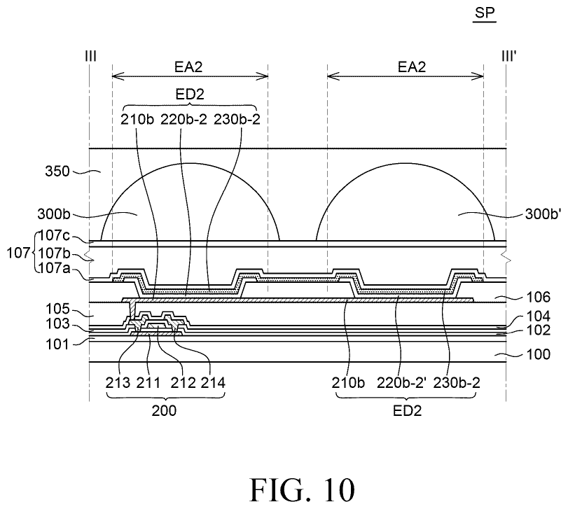

FIG. 7 is a plan view of a pixel of a display apparatus according to another exemplary embodiment of the present disclosure. FIG. 8 is a plan view of a sub pixel of a display apparatus according to another exemplary embodiment of the present disclosure. FIG. 9 is a cross-sectional view taken along line II-II′ of FIG. 8. FIG. 10 is a cross-sectional view taken along line III-III′ of FIG. 8.

Referring to FIG. 7, in the first sub pixel SP1, the second sub pixel SP2, and the third sub pixel SP3 configuring one pixel PX, a wiring line supplying the first low-potential power voltage ELVSS1 is commonly connected, and separately, a wiring line supplying the second low-potential power voltage ELVSS2 is commonly connected.

Each of the first sub pixel SP1, the second sub pixel SP2, and the third sub pixel SP3 may include one anode electrode 210b, three emission layers 220b-1, 220b-2, and 220b-2′ disposed on the one anode electrode 210b, one first cathode electrode 230b-1 disposed on the one emission layer 220b-1, and one second cathode electrode 230b-2 disposed on the two emission layers 220b-2 and 220b-2′. At this time, the first cathode electrode 230b-1 is connected to a first low-potential power line supplying the first low-potential power voltage ELVSS1. The one second cathode electrode 230b-2 is connected to a second low-potential power line supplying the second low-potential power voltage ELVSS2.

Referring to FIG. 7, the three emission layers 220b-1, 220b-2, and 220b-2′ are disposed in two areas spaced apart along a longitudinal direction of the anode electrode 210b, in which the one emission layer 220b-1 is disposed in one area, and the two emission layers 220b-2 and 220b-2′ may be disposed apart from each other in the other area. A size of the one emission layer 220b-1 may be larger than a size of each of the two emission layers 220b-2 and 220b-2′.

Accordingly, as illustrated in FIGS. 8 and 9, one sub pixel may include the first light emitting diode ED1 including the anode electrode 210b, the one emission layer 220b-1, and the first cathode electrode 230b-1. In addition, one sub pixel may include one second light emitting diode ED2 including the anode electrode 210b, another emission layer 220b-2, and one second cathode electrode 230b-2. Further, one sub pixel may include another second light emitting diode ED2 including the anode electrode 210b, another emission layer 220b-2′, and one second cathode electrode 230b-2.

As such, one sub pixel may include one first light emitting diode ED1 and two second light emitting diodes ED2, and the anode electrode 210b of the one first light emitting diode ED1 is integrally formed with the anode electrode 210b of the two second light emitting diodes ED2. In addition, the cathode electrode 230b-2 of the two second light emitting diodes ED2 is integrally formed on the two emission layers 220b-2 and 220b-2′. Also, the cathode electrode 230b-1 of the one first light emitting diode ED1 and the cathode electrode 230b-2 of the two second light emitting diodes ED2 are electrically separated. That is, in one sub pixel, the two second light emitting diodes ED2 share the anode electrode 210b and the cathode electrode 230b-2.

Meanwhile, referring to FIGS. 8 to 10 together, a display apparatus according to another exemplary embodiment of the present disclosure may include lenses 300b and 300b′ disposed to respectively cover emission areas EA2 of the two second light emitting diodes ED2 in each sub pixel SP. In FIGS. 8 to 10, the lenses 300b and 300b′ of the display apparatus according to another exemplary embodiment of the present disclosure are described as semi-cylindrical lenses illustrated in FIG. 5B, but shapes of the lenses 300b and 300b′ are not limited thereto.

As illustrated in FIGS. 9 and 10, in one sub pixel SP, no lens is disposed above the one first light emitting diode ED1, and a first lens 300b and a second lens 300b′ are disposed above the two second light emitting diodes ED2 so as to overlap emission areas EA2, respectively.

When the share mode is selected, the power supply unit 150 supplies low-potential power voltage ELVSS to both the first light emitting diode ED1 and the two second light emitting diodes ED2. Accordingly, the first low-potential power voltage ELVSS1 is applied to the second electrode 230b-1 of the first light emitting diode ED1 so that the first light emitting diode ED1 emits light, and the second low-potential power voltage ELVSS2 is applied to the second electrode 230b-2 of each of the two second light emitting diodes ED2 so that the two second light emitting diodes ED2 also emit light together. Thus, in the share mode, both the first light emitting diode ED1 and the two second light emitting diodes ED2 emit light to display an image in a wide viewing angle.

On the other hand, when the privacy mode is selected, the power supply unit 150 supplies low-potential power voltage ELVSS only to the two second light emitting diodes ED2 among the first light emitting diode ED1 and the two second light emitting diodes ED2. Accordingly, second low-potential power voltage ELVSS2 is applied to the second electrode 230b-2 of each of the two second light emitting diodes ED2 so that the two second light emitting diodes ED2 emit light, but the low-potential power voltage is not applied to the second electrode 230b-1 of the first light emitting diode ED1 so that the first light emitting diode ED1 does not operate. Thus, in the privacy mode, only the two second light emitting diodes ED2 in sub pixel SP emit light to display an image in a narrow viewing angle.

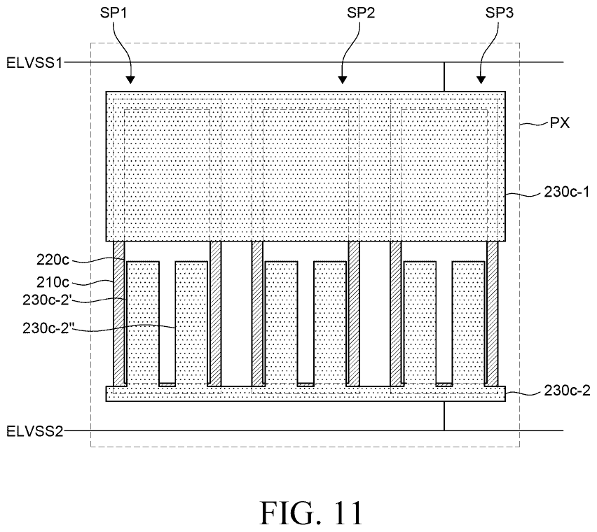

Next, referring to FIGS. 11 to 14, a pixel structure and a pixel driving method of a display apparatus according to still another exemplary embodiment of the present disclosure will be described in detail. For convenience of explanation, in FIGS. 11 to 14, descriptions overlapping with those of FIGS. 4 to 6 will be omitted.

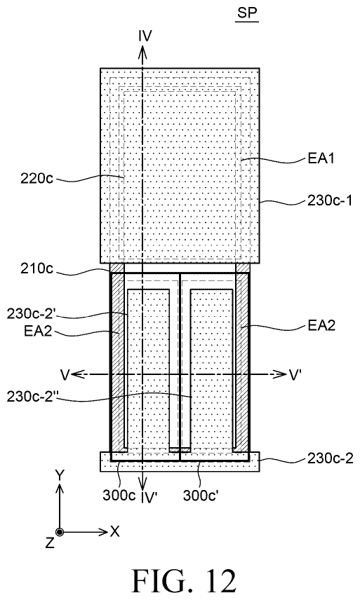

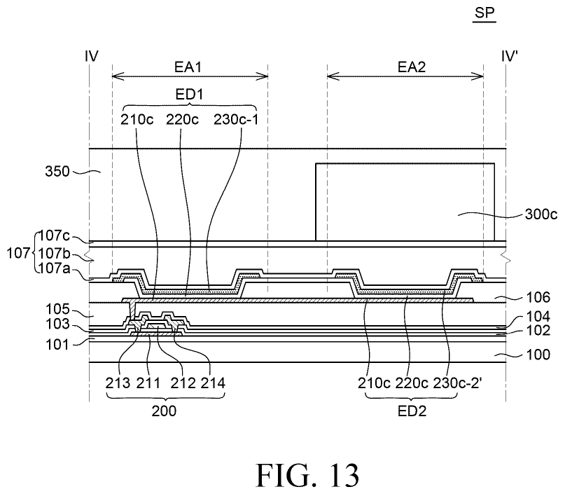

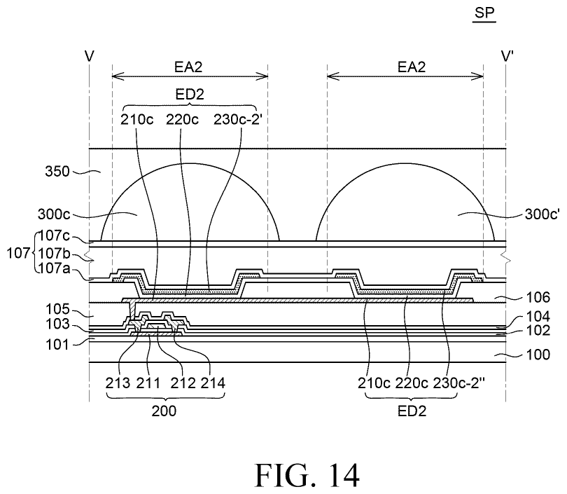

FIG. 11 is a plan view of a pixel of a display apparatus according to still another exemplary embodiment of the present disclosure. FIG. 12 is a plan view of a sub pixel of a display apparatus according to still another exemplary embodiment of the present disclosure. FIG. 13 is a cross-sectional view taken along line IV-IV′ of FIG. 12. FIG. 14 is a cross-sectional view taken along line V-V′ of FIG. 12.

Referring to FIG. 11, in the first sub pixel SP1, the second sub pixel SP2, and the third sub pixel SP3 configuring one pixel PX, a wiring line supplying the first low-potential power voltage ELVSS1 is commonly connected, and separately, a wiring line supplying the second low-potential power voltage ELVSS2 is commonly connected.

Each of the first sub pixel SP1, the second sub pixel SP2, and the third sub pixel SP3 may include one anode electrode 210c, one emission layer 220c disposed on the one anode electrode 210c, and three cathode electrodes 230c-1, 230c-2′, and 230c-2″ disposed on the one emission layer 220c. At this time, the one cathode electrode 230c-1 is connected to a first low-potential power line supplying the first low-potential power voltage ELVSS1. The two cathode electrodes 230c-2′ and 230c-2″ are respectively connected to second low-potential power lines supplying the second low-potential power voltage ELVSS2. At this time, the two cathode electrodes 230c-2′ and 230c-2″ are connected at one end to a common body 230c-2 (also referred to as ‘a common conductive body 230c-2’).

Referring to FIGS. 11 and 12, the two cathode electrodes 230c-2′ and 230c-2″ may be branches branched from the common body 230c-2, and the common body 230c-2 does not overlap with the emission layer 220c. A size of each of the two cathode electrodes 230c-2′ and 230c-2″ may be smaller than a size of the one cathode electrode 230c-1.

Accordingly, as illustrated in FIGS. 13 and 14, one sub pixel may include the first light emitting diode ED1 including the anode electrode 210c, the emission layer 220c, and the first cathode electrode 230c-1. In addition, one sub pixel may include one second light emitting diode ED2 including the anode electrode 210c, the emission layer 220c, and one second cathode electrode 230c-2′. Further, one sub pixel may include another second light emitting diode ED2 including the anode electrode 210c, the emission layer 220c, and the other second cathode electrode 230c-2″.

As such, one sub pixel may include the one first light emitting diode ED1 and the two second light emitting diodes ED2, and the anode electrode 210c of the one first light emitting diode ED1 is integrally formed with the anode electrode 210c of the two second light emitting diodes ED2. The cathode electrodes 230c-2′ and 230c-2″ of the two second light emitting diodes ED2 are connected at one end to the one cathode electrode 230c-2, and second low-potential power voltage ELVSS2 may be applied thereto simultaneously. In addition, the cathode electrode 230c-1 of the one first light emitting diode ED1 and the cathode electrodes 230c-2′ and 230c-2″ of the two second light emitting diodes ED2 are electrically separated.

As such, in one sub pixel, the two second light emitting diodes ED2 share the anode electrode 210c and the emission layer 220c. That is, the emission layer 220a of the first light emitting diode ED1 and the emission layer 220a of the two second light emitting diodes ED2 are integrally formed. On the emission layers 220a of the first light emitting diode ED1 and the two second light emitting diodes ED2, the second electrode 230c-1 of the first light emitting diode ED1 and the second electrodes 230c-2′ and 230c-2″ of the two second light emitting diodes ED2 are disposed apart from each other along a first direction (i.e., Y direction). In addition, on the emission layers 220a of the two second light emitting diodes ED2, the second electrodes 230c-2′ and 230c-2″ are disposed apart from each other along a second direction (i.e., X direction) crossing the first direction (i.e., Y direction).

Meanwhile, referring to FIGS. 12 to 14 together, a display apparatus according to still another exemplary embodiment of the present disclosure may include lenses 300c and 300c′ disposed to respectively cover the emission areas EA2 of the two second light emitting diodes ED2 in each sub pixel SP. In FIGS. 12 to 14, the lenses 300c and 300c′ of the display apparatus according to still another exemplary embodiment of the present disclosure are described as semi-cylindrical lenses illustrated in FIG. 5B, but shapes of the lenses 300c and 300c′ are not limited thereto.

As illustrated in FIGS. 13 and 14, in one sub pixel SP, no lens is disposed above the first light emitting diode ED1, and the first lens 300c and the second lens 300c′ are disposed above the two second light emitting diodes ED2 so as to overlap the emission areas EA2, respectively.

When the share mode is selected, the power supply unit 150 supplies the low-potential power voltage ELVSS to both the first light emitting diode ED1 and the two second light emitting diodes ED2. Accordingly, the first low-potential power voltage ELVSS1 is applied to the second electrode 230c-1 of the first light emitting diode ED1 so that the first light emitting diode ED1 emits light, and the second low-potential power voltage ELVSS2 is applied to second electrode 230c-2 of each of the two second light emitting diodes ED2 so that the two second light emitting diodes ED2 also emit light. As the second low-potential power voltage ELVSS2 is applied to the second electrode 230c-2, the second low-potential power voltage ELVSS2 is also applied to the second electrode 230c-2′ and the second electrode 230c-2″, which are branches of the second electrode 230c-2, respectively. Thus, in the share mode, both the first light emitting diode ED1 and the two second light emitting diodes ED2 emit light to display an image in a wide viewing angle.

On the other hand, when the privacy mode is selected, the power supply unit 150 supplies low-potential power voltage ELVSS only to the two second light emitting diodes ED2 among the first light emitting diode ED1 and the two second light emitting diodes ED2. Accordingly, the second low-potential power voltage ELVSS2 is applied to the second electrodes 230c-2′ and 230c-2″ of each of the two second light emitting diodes ED2 so that the two second light emitting diodes ED2 emit light, but the low-potential power voltage is not applied to the second electrode 230c-1 of the first light emitting diode ED1, so that the first light emitting diode ED1 does not operate. Thus, in the privacy mode, only the two second light emitting diodes ED2 in sub pixel SP emit light to display an image in a narrow viewing angle.

As such, the display apparatus according to various exemplary embodiments of the present disclosure may implement an image in a wide viewing angle by driving both the first light emitting diode and the second light emitting diodes in the share mode through divided driving of cathodes of the first light emitting diode and the second light emitting diodes configuring one sub pixel and may implement an image in a narrow viewing angle in the privacy mode by driving only a part of the first light emitting diode and the second light emitting diodes.

For example, A privacy mode for displaying a private content image viewable only by a specific user by driving pixels having a narrow viewing angle disposed in a partial area of a screen, and a share mode for displaying a shared content image viewable by a plurality of users by driving pixels having a wide viewing angle disposed in another area of the screen may be simultaneously provided. Alternatively, an image in the privacy mode and an image in the share mode may be provided alternately in one screen area depending on a user's selection.

In addition, a display apparatus according to various exemplary embodiments of the present disclosure may enable switching between the share mode and the privacy mode only by dividing cathodes of the first light emitting diode and the second light emitting diodes configuring one sub pixel, thereby providing control of the share mode and the privacy mode with minimal change in specifications of the pixel driving circuit.

The exemplary embodiments of the present disclosure can also be described as follows:

In one embodiment, as shown in FIG. 6, a display apparatus includes a plurality of sub-pixels arranged on a substrate. Each sub-pixel may include a common anode electrode disposed on the substrate and shared by a first light emitting diode ED1 and a plurality of second light emitting diodes ED2. The common anode electrode 210a may be formed of a conductive material such as indium tin oxide (ITO), indium zinc oxide (IZO), or another transparent conductive layer and may serve as a shared positive electrode for multiple emission regions. At least one emission layer 220a may be disposed on the common anode electrode. A first cathode electrode 230a-1 may be disposed on the at least one emission layer corresponding to the first light emitting diode ED1, and a plurality of second cathode electrodes 230a-2 may be disposed on the at least one emission layer corresponding to the plurality of second light emitting diodes. The first cathode electrode and the plurality of second cathode electrodes may be electrically separated from one another such that the first and second light emitting diodes can be individually addressed. The display apparatus may further include at least one lens disposed on either the first light emitting diode, the plurality of second light emitting diodes, or on both. The lens or lenses may be configured to control the path of light emitted from the corresponding light emitting diodes. The first light emitting diode and the plurality of second light emitting diodes may be configured to be driven separately or together to vary a viewing angle of an image displayed by the apparatus, such that a narrow viewing angle (privacy mode) or a wide viewing angle (share mode) may be selectively provided.

In some embodiments, the at least one emission layer may include a single emission layer 220a that is shared by the first light emitting diode ED1 and the plurality of second light emitting diodes ED2. The plurality of second cathode electrodes 230a-2 may be spaced apart from each other in plan view (i.e., when viewed along a direction perpendicular to the substrate surface), allowing each second cathode electrode to correspond to a distinct emission area. In such configurations, the at least one lens may be disposed on both the first light emitting diode and the plurality of second light emitting diodes, thereby covering the emission areas of all light emitting diodes in each sub-pixel to control emitted light uniformly across the sub-pixel.

In an additional embodiment, the first light emitting diode may be disposed between adjacent second light emitting diodes of the plurality of second light emitting diodes. The single emission layer may extend continuously between the adjacent second light emitting diodes so that it is shared by both the first and second light emitting diodes. This arrangement allows efficient optical blending and enables selective driving of the first and second light emitting diodes to achieve different emission patterns or viewing angles across the same continuous emission layer.

In another embodiment, the at least one emission layer may include multiple discrete emission layers—for example, a first emission layer 220b-1, a second emission layer 220b-2, and a third emission layer 220b-2′—that are spaced apart from each other in plan view (see FIGS. 9 and 10). The first emission layer may correspond to the first light emitting diode, the second emission layer may correspond to one of the second light emitting diodes of the plurality, and the third emission layer may correspond to another one of the second light emitting diodes of the plurality. Each emission layer may include an organic or inorganic emissive material configured to emit light of the same or different colors depending on the sub-pixel configuration.

In certain configurations, the at least one lens may be disposed on the plurality of second light emitting diodes so as to overlap the plurality of second light emitting diodes in plan view, while not overlapping the first light emitting diode (see FIG. 9). Such placement allows directional control of the light emitted from the second light emitting diodes to form a narrow viewing angle, while the first light emitting diode can emit without lens-induced optical confinement when a wide viewing angle is desired.

In some embodiments, the plurality of second cathode electrodes may include a first of the second cathode electrodes that overlaps the first emission layer in plan view and another of the second cathode electrodes that overlaps the second and third emission layers in plan view (see FIG. 10). This configuration permits simultaneous or selective activation of different emission regions while maintaining electrical independence between cathode electrodes.

In another embodiment, the plurality of second cathode electrodes may include a third cathode electrode 230c-1, a fourth cathode electrode 230c-2', and a fifth cathode electrode 230c-2″, together with a common conductive body 230c-2 that is connected to the fourth 230c-2′ and fifth cathode electrodes 230c-2″. The common conductive body 230c-2 may serve as a shared bus or connector while being non-overlapping with the emission layers in plan view, thereby reducing unwanted optical shading or electrical interference with the emissive regions.

In the above embodiment, the fourth and fifth cathode electrodes may extend from the common conductive body toward the third cathode electrode in plan view and may be spaced apart from the third cathode electrode. The spatial separation may electrically isolate the third cathode electrode while allowing the fourth and fifth cathode electrodes to share a common potential through the common conductive body. The geometry of this layout may be optimized for uniform current distribution and stable emission characteristics.

In still another embodiment, the fourth and fifth cathode electrodes that extend from the common conductive body may be integrally formed with the common conductive body, such that the fourth cathode electrode, the fifth cathode electrode, and the common conductive body constitute a single continuous conductive structure. Such an integral formation can improve manufacturing reliability and electrical stability across the connected cathode electrodes.

In another embodiment, the at least one emission layer may include a single emission layer that is shared by the first light emitting diode and the plurality of second light emitting diodes, and the at least one lens may be disposed on the plurality of second light emitting diodes. This configuration allows the shared emission layer to generate light for both diode groups, while the lenses over the second light emitting diodes modify the emission distribution for privacy or directional viewing control. The described structures, materials, and arrangements may be implemented in various display types, including organic light emitting diode (OLED), micro-LED, or quantum-dot displays, to provide selective control of emission angle and brightness uniformity.

The exemplary embodiments of the present disclosure can further be described as follows:

According to an aspect of the present disclosure, there is provided a display apparatus. The display apparatus includes a substrate in which a plurality of sub pixels is defined.
The display apparatus further includes a first light emitting diode disposed on the substrate in each of the plurality of sub pixels and including a first electrode, an emission layer, and a second electrode. The display apparatus further includes a plurality of second light emitting diodes disposed on the substrate in each of the plurality of sub pixels and including a first electrode, an emission layer, and a second electrode. And the display apparatus further includes a lens disposed on the first light emitting diode or the plurality of second light emitting diodes in the plurality of sub pixels and controlling a path of light emitted from the first light emitting diode or the plurality of second light emitting diodes. The second electrode of the first light emitting diode and the second electrode of the plurality of second light emitting diodes are electrically separated.

The first electrode of the first light emitting diode and the first electrode of the plurality of second light emitting diodes may be integrally formed.

The display apparatus may further include a power supply unit configured to supply a high potential power voltage and a low potential power voltage to the plurality of sub pixels. The power supply unit may supply the low potential power voltage to both the first light emitting diode and the plurality of second light emitting diodes in a first mode, and supply the low potential power voltage to only one of the first light emitting diode and the plurality of second light emitting diodes in a second mode.

The emission layer of the first light emitting diode and the emission layers of the plurality of second light emitting diodes may be integrally formed. The second electrode of the first light emitting diode and the second electrodes of the plurality of second light emitting diodes may be disposed spaced apart from each other in one direction on the emission layer of the first light emitting diode and the emission layers of the plurality of second light emitting diodes.

The lens may be a semi-cylindrical lens extending in one direction. The second electrode of the first light emitting diode and the second electrodes of the plurality of second light emitting diodes may respectively extend along a longitudinal direction in which the lens extends.

One lens may be disposed on the first light emitting diode and the plurality of second light emitting diodes.

The second electrode of the first light emitting diode may be disposed between two of the second electrodes of the plurality of second light emitting diodes.

The power supply unit may supply the low potential power voltage to only the first light emitting diode among the first light emitting diode and the plurality of second light emitting diodes in the second mode.

The emission layer of the first light emitting diode and the emission layers of the plurality of second light emitting diodes may be disposed spaced apart from each other. The second electrodes of the plurality of second light emitting diodes may be integrally disposed on the emission layers of the plurality of second light emitting diodes spaced apart from each other.

The plurality of second light emitting diodes may share the first electrode and the second electrode with each other.

The lens may be disposed in a plurality corresponding to each of the plurality of second light emitting diodes among the first light emitting diode and the plurality of second light emitting diodes.

The power supply unit may supply the low potential power voltage to only the plurality of second light emitting diodes among the first light emitting diode and the plurality of second light emitting diodes in the second mode.

The emission layer of the first light emitting diode and the emission layers of the plurality of second light emitting diodes may be integrally formed. The second electrode of the first light emitting diode and the second electrodes of the plurality of second light emitting diodes may be disposed spaced apart from each other along a first direction on the emission layer of the first light emitting diode and the emission layers of the plurality of second light emitting diodes. And the second electrodes of the plurality of second light emitting diodes may be disposed spaced apart from each other along a second direction intersecting the first direction on the emission layers of the plurality of second light emitting diodes.

The second electrodes of the plurality of second light emitting diodes may have one end connected to a common body. The body may be non-overlapped with the emission layers of the plurality of second light emitting diodes.

The lens may be disposed in a plurality corresponding to each of the plurality of second light emitting diodes among the first light emitting diode and the plurality of second light emitting diodes.

The power supply unit may supply the low potential power voltage to only the plurality of second light emitting diodes among the first light emitting diode and the plurality of second light emitting diodes in the second mode.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display apparatus, comprising:
a substrate in which a plurality of sub pixels is defined;
a first light emitting diode disposed on the substrate in each of the plurality of sub pixels and including a first electrode, an emission layer, and a second electrode;
a plurality of second light emitting diodes disposed on the substrate in each of the plurality of sub pixels and including a first electrode, an emission layer, and a second electrode; and
a lens disposed on the first light emitting diode or the plurality of second light emitting diodes in the plurality of sub pixels and, the lens configured to control a path of light emitted from the first light emitting diode or the plurality of second light emitting diodes,
wherein the second electrode of the first light emitting diode and the second electrode of the plurality of second light emitting diodes are electrically separated.

2. The display apparatus according to claim 1, wherein the first electrode of the first light emitting diode and the first electrode of the plurality of second light emitting diodes are integrally formed.

3. The display apparatus according to claim 2, further comprising:
a power supply unit configured to supply a high potential power voltage and a low potential power voltage to the plurality of sub pixels,
wherein the power supply unit supplies the low potential power voltage to both the first light emitting diode and the plurality of second light emitting diodes in a first mode, and supplies the low potential power voltage to only one of the first light emitting diode and the plurality of second light emitting diodes in a second mode.

4. The display apparatus according to claim 3, wherein the emission layer of the first light emitting diode and the emission layers of the plurality of second light emitting diodes are integrally formed,
wherein the second electrode of the first light emitting diode and the second electrodes of the plurality of second light emitting diodes are disposed spaced apart from each other in one direction on the emission layer of the first light emitting diode and the emission layers of the plurality of second light emitting diodes, and
wherein one lens is disposed on the first light emitting diode.

5. The display apparatus according to claim 4, wherein the lens is a semi-cylindrical lens extending in one direction, and
wherein the second electrode of the first light emitting diode and the second electrodes of the plurality of second light emitting diodes respectively extend along a longitudinal direction in which the lens extends.

6. The display apparatus according to claim 4, wherein the second electrode of the first light emitting diode is disposed between two of the second electrodes of the plurality of second light emitting diodes.

7. The display apparatus according to claim 6, wherein the power supply unit supplies the low potential power voltage to only the first light emitting diode among the first light emitting diode and the plurality of second light emitting diodes in the second mode.

8. The display apparatus according to claim 3, wherein the emission layer of the first light emitting diode and the emission layers of the plurality of second light emitting diodes are disposed spaced apart from each other,
wherein the second electrodes of the plurality of second light emitting diodes are integrally disposed on the emission layers of the plurality of second light emitting diodes spaced apart from each other,
wherein the plurality of second light emitting diodes shares the first electrode and the second electrode with each other, and
wherein the lens is disposed in a plurality corresponding to each of the plurality of second light emitting diodes among the first light emitting diode and the plurality of second light emitting diodes.

9. The display apparatus according to claim 8, wherein the power supply unit supplies the low potential power voltage to only the plurality of second light emitting diodes among the first light emitting diode and the plurality of second light emitting diodes in the second mode.

10. The display apparatus according to claim 3, wherein the emission layer of the first light emitting diode and the emission layers of the plurality of second light emitting diodes are integrally formed,
wherein the second electrode of the first light emitting diode and the second electrodes of the plurality of second light emitting diodes are disposed spaced apart from each other along a first direction on the emission layer of the first light emitting diode and the emission layers of the plurality of second light emitting diodes,
wherein the second electrodes of the plurality of second light emitting diodes are disposed spaced apart from each other along a second direction intersecting the first direction on the emission layers of the plurality of second light emitting diodes, and
wherein the lens is disposed in a plurality corresponding to each of the plurality of second light emitting diodes among the first light emitting diode and the plurality of second light emitting diodes.

11. The display apparatus according to claim 10, wherein the second electrodes of the plurality of second light emitting diodes have one end connected to a common body, and
wherein the common body is non-overlapped with the emission layers of the plurality of second light emitting diodes.

12. The display apparatus according to claim 10, wherein the power supply unit supplies the low potential power voltage to only the plurality of second light emitting diodes among the first light emitting diode and the plurality of second light emitting diodes in the second mode.

13. A display apparatus, comprising:
a plurality of sub-pixels arranged on a substrate, each sub-pixel including:
a common anode electrode disposed on the substrate and shared by a first light emitting diode and a plurality of second light emitting diodes;
at least one emission layer disposed on the common anode electrode;
a first cathode electrode disposed on the at least one emission layer corresponding to the first light emitting diode, and
a plurality of second cathode electrodes disposed on the at least one emission layer corresponding to the plurality of second light emitting diodes, the first cathode electrode and the plurality of second cathode electrodes being electrically separated;
at least one lens disposed on the first light emitting diode or the plurality of second light emitting diodes,
wherein the first light emitting diode and the plurality of second light emitting diodes are configured to be driven separately or together to vary a viewing angle of an image.

14. The display apparatus according to claim 13, wherein the at least one emission layer includes a single emission layer that is shared by the first light emitting diode and the plurality of second light emitting diodes,
wherein the plurality of second cathode electrodes is spaced apart from each other in plan view,
wherein the at least one lens is disposed on both the first light emitting diode and the plurality of second light emitting diodes,
wherein the first light emitting diode is disposed between adjacent second light emitting diodes of the plurality of second light emitting diodes, and
wherein the single emission layer extends between the adjacent second light emitting diodes such that the single emission layer is shared by both the first light emitting diode and the plurality of second light emitting diodes.

15. The display apparatus according to claim 13, wherein the at least one emission layer includes a first emission layer, a second emission layer, and a third emission layer that is spaced apart from each other in plan view,
wherein the first emission layer corresponds to the first light emitting diode, the second emission layer corresponds to one of second light emitting diode of the plurality of second light emitting diodes, and the third emission layer corresponds to another one of second light emitting diode of the plurality of second light emitting diodes,
wherein the at least one lens is disposed on the plurality of second light emitting diodes to overlap the plurality of second light emitting diodes in plan view, and
wherein the at least one lens do not overlap the first light emitting diode in plan view.

16. The display apparatus according to claim 15, wherein the plurality of second cathode electrodes includes one of second cathode electrode that overlaps the first emission layer in a plan view and another one of second cathode electrode that overlaps the second and third emission layers in plan view.

17. The display apparatus according to claim 13, wherein the plurality of second cathode electrodes includes a third cathode electrode, a fourth cathode electrode, a fifth cathode electrode, and a common conductive body that is connected to the fourth cathode electrode and the fifth cathode electrode, and
wherein the common conductive body does not overlap with the at least one emission layer in plan view.

18. The display apparatus according to claim 17, wherein the fourth cathode electrode and the fifth cathode electrode extends from the common conductive body towards the third cathode electrode in plan view, and
wherein the fourth and fifth cathode electrodes are spaced apart from the third cathode electrode in plan view.

19. The display apparatus according to claim 17, wherein the fourth cathode electrode and the fifth cathode electrode that extends from the common conductive body are integrally formed.

20. The display apparatus according to claim 17, wherein the at least one emission layer includes a single emission layer that is shared by the first light emitting diode and the plurality of second light emitting diodes, and
wherein the at least one lens is disposed on the plurality of second light emitting diodes.
